(19) United States
(12) Patent Application Publication
(10) Pub. No.: US 2007/0284970 A1
(43) Pub. Date: Dec. 13, 2007

(54) Piezoelectric oscillator and method of manufacturing the same

(76) Inventor: Noriyuki Fujita, Saitama (JP)

Correspondence Address: MCDERMOTT WILL & EMERY LLP, 600 13TH STREET, NW, WASHINGTON, DC, 20005-3096, US

(21) Appl. No.: 11/802,414

(22) Filed: May 22, 2007

(30) Foreign Application Priority Data
May 23, 2006 (JP) P.2006-142771
May 9, 2007 (JP) P.2006-124783

(51) Int. Cl. H01L 41/04

(52) U.S. Cl. 310/344

(57) ABSTRACT

A piezoelectric oscillator includes a semiconductor chip which includes an electrical circuit, a piezoelectric vibrator which is provided on a main surface of the semiconductor chip, and an external electrode which is provided on the main surface of the semiconductor chip.

### BACKGROUND OF THE INVENTION

The present invention relates to a piezoelectric oscillator and a method of manufacturing the same.

In recent years, mobile phones have been widely spread and piezoelectric oscillators are used as reference frequency oscillators for the mobile phones. The piezoelectric oscillator is requested to have a function as a high-precision reference frequency oscillator and to be made small, thin, and low price as a component. As the request is recently becoming tougher, 32 mm×25 mm is predominating as the component size of the piezoelectric oscillator. Further, a size of 25 mm×20 mm or 20 mm×16 mm is being requested.

In the related art, a piezoelectric oscillator is configured to include a ceramic substrate, a piezoelectric vibrator, and a semiconductor chip, so as to meet a request to make the piezoelectric oscillator small, thin, and low price.

A piezoelectric oscillator in the related art will now be described with reference to the accompanying drawing. FIG. 10 is a cross-sectional view illustrating an example of the configuration of a piezoelectric oscillator in the related art.

In the configuration shown in FIG. 10, reference numeral 1 denotes a piezoelectric vibrator, reference numeral 2 denotes a ceramic substrate (including a leg part 2a and a lower part 2b), reference numeral 3 denotes an external electrode, reference numeral 4 denotes a semiconductor chip, reference numeral 5 denotes a first wiring layer formed on the semiconductor chip, reference numeral 6 denotes a bump electrode for electrically connecting the piezoelectric vibrator 1 and the semiconductor chip 4 with each other, reference numeral 7 denotes a second wiring layer formed on the ceramic substrate 2, reference numeral 8 denotes a through hole for electrically connecting the piezoelectric vibrator 1 and the second wiring layer 7 with each other, and reference numeral 9 denotes a resin for fixing the semiconductor chip.

The piezoelectric vibrator 1, the external electrode 3, and the semiconductor chip 4 are electrically connected to one another by the first wiring layer 5 formed on the semiconductor chip 4 and the second wiring layer 7 formed on the ceramic substrate 2.

In order to mount a piezoelectric oscillator on a substrate or the like of a mobile phone set, an external electrode is needed. In the known example shown in FIG. 10, since the external electrode 3 is formed on a lowermost part (lower surface part of the leg part 2a) of the ceramic substrate 2, the piezoelectric oscillator can be mounted on the substrate of the mobile phone set through the external electrode 3.

A piezoelectric oscillator having the same basic structure as in the known example shown in FIG. 7 is disclosed in JP-A-7-106891, for example. That is, JP-A-7-106891 discloses a surface mount type piezoelectric oscillator having a basic structure in which a semiconductor chip is accommodated in a recessed part of a ceramic substrate and a resin layer is formed, a piezoelectric vibrator is mounted on the ceramic substrate, and the semiconductor chip and the piezoelectric vibrator are electrically connected to each other through an electrode passing through the ceramic substrate.

However, in the piezoelectric oscillator having the configuration in the related art, the ceramic substrate is an essential element and the piezoelectric vibrator, the ceramic substrate, and the semiconductor chip are stacked to overlap in the vertical direction. Accordingly, it is difficult to make the piezoelectric oscillator thin.

Further, since the semiconductor chip is mounted between inner walls (that is, in a recessed part) of the ceramic substrate, which is molded beforehand, from a back side, the dimensional allowance for mounting is required for the inner walls of the ceramic substrate and ends of the semiconductor chip. As a result, a problem occurs in that it is difficult to make the piezoelectric oscillator small.

For example, in order to realize a piezoelectric oscillator having a size of 2.5 mm×2.0 mm using a ceramic substrate having walls in four directions, the chip size equal to or smaller than at least 1.7 mm×1.2 mm is requested to a semiconductor chip assuming that 0.4 mm for both the thickness of each inner wall of the ceramic substrate and the dimensional allowance necessary for chip mounting is needed at each side. That is, in order to realize a piezoelectric oscillator having a size of 2.0 mm×1.6 mm, the chip size equal to or smaller than at least 1.2 mm×1.8 mm is requested, which is difficult to be realized.

In addition, the ceramic substrate is expensive. Accordingly, for example, in order to realize a piezoelectric oscillator that is small, thin, and low price and has a size of 2.0 mm×1.6 mm, it is necessary to reexamine the configuration of the piezoelectric oscillator.

### SUMMARY OF THE INVENTION

The present invention has been made to solve such problems in the related art, and it is an object of the present invention to provide a piezoelectric oscillator that can be made small, thin, and low price and a method of manufacturing the same.

In order to achieve the above object, according to the present invention, there is provided a piezoelectric oscillator, comprising:

a semiconductor chip which includes an electrical circuit;

a piezoelectric vibrator which is provided on a main surface of the semiconductor chip; and

an external electrode which is provided on the main surface of the semiconductor chip.

Preferably, a height of the external electrode is greater than a thickness of the piezoelectric vibrator.

In the invention, since the piezoelectric vibrator is provided on the main surface of the semiconductor chip without using a ceramic substrate, and the external its height being higher than the thickness of the piezoelectric vibrator is formed on the same main surface (that is, near the piezoelectric vibrator). Therefore, a surface mounting of the element onto a mounting substrate becomes possible. That is, by adopting a chip-size mounting structure due to the mounting structure of the piezoelectric vibrator, each piezoelectric oscillator can be made small, thin, and low price. That is, in the piezoelectric oscillator according to the above configuration, it is not necessary to accommodate the semiconductor chip in a recessed part of a ceramic substrate, unlike the related art. Accordingly, since it is not necessary to consider a positioning margin or the like, the planar size of a piezoelectric oscillator is basically determined by a semiconductor chip size. In addition, the piezoelectric oscillator can be made sufficiently thin because the ceramic substrate is not provided, and it is possible to manufacture the piezoelectric oscillator at a low cost because the expensive ceramic substrate is not needed.

In the piezoelectric oscillator described above, preferably, the piezoelectric vibrator is electrically connected to the electrical circuit through a wiring layer provided on the semiconductor chip, and the external electrode is electrically connected to the electrical circuit through the wiring layer. That is, the piezoelectric vibrator is connected to the external electrode through the electrical circuit of the semiconductor ship without having a separate external connecting terminal.

In the invention, only the piezoelectric vibrator and the semiconductor chip having the electrical circuit are included in the piezoelectric oscillator, and the external electrode is formed on the semiconductor chip. Accordingly, since it is not necessary to consider the dimensional allowance for inner walls of the ceramic substrate or semiconductor chip mounting unlike the related art. For example, in the case of a semiconductor chip size of 2.0 mm×1.6 mm, it is possible to realize a piezoelectric oscillator having a size of 2.0 mm×1.6 mm. That is, it becomes possible to make the piezoelectric oscillator thin and small and to make the piezoelectric oscillator at a low cost without using the expensive ceramic substrate.

Further, in the piezoelectric oscillator described above, preferably, the wiring layer is configured by a multi-layered wiring structure. The wiring layer includes a first wiring layer, an interlayer insulating layer which covers the first wiring layer, and a second wiring layer which is connected to the first wiring layer through a contact hole provided in the interlayer insulating layer.

Since the multi-layered wiring structure is adopted, degree of freedom of pattern or size of an uppermost wiring layer in the multi-layered wiring structure is improved. Accordingly, degree of freedom of mounting of the piezoelectric vibrator and degree of freedom of arrangement of the external electrodes are also improved. This contributes to making the piezoelectric oscillator much smaller and thinner.

Furthermore, in the piezoelectric oscillator described above, preferably, a resin layer is formed on the main surface of the semiconductor chip so as to cover the piezoelectric vibrator and a part of the external electrode. More preferably, the resin layer is comprised of an epoxy resin.

Since the piezoelectric vibrator is covered by the resin layer, the piezoelectric vibrator is protected by the resin layer. Accordingly, the reliability of a dust-proof or moisture-resistant surface is improved. In addition, since the piezoelectric vibrator and the external electrode are fixed due to the resin layer, the mechanical strength of the piezoelectric oscillator is improved. As a result, it is possible to realize a highly reliable piezoelectric oscillator.

In addition, according to another aspect of the invention, a method of manufacturing a piezoelectric oscillator, comprising:

providing a plurality of piezoelectric vibrators on a common semiconductor substrate;

forming a plurality of external electrodes so as to be correspond to the piezoelectric vibrators;

performing an electrical inspection of each of the piezoelectric vibrators in a state that the piezoelectric vibrators are provided on the common semiconductor substrate; and

dicing the common semiconductor substrate so that a plurality of piezoelectric oscillators are individually cut out, each of the piezoelectric oscillators having a configuration in which each of the piezoelectric vibrators is provided on a semiconductor chip.

Preferably, a height of each of the external electrodes is greater than a thickness of each of the piezoelectric vibrators. That is, the external electrode is formed so as to protrude from an end face of the piezoelectric vibrators.

Preferably, he external electrode is substantially shaped in a square pillar.

In the invention, since the electrical inspection of each piezoelectric vibrator is completed under a state in which the plurality of piezoelectric vibrators is mounted on a common semiconductor substrate, it is sufficient to perform a simple inspection for piezoelectric oscillators separated by dicing, or it may be possible to omit the inspection. Accordingly, it is possible to efficiently manufacture a piezoelectric oscillator that has a new structure in which a ceramic substrate is not used and that is thin, small, and low price, and as a result, it is possible to produce piezoelectric oscillators in large quantities.

In the method of manufacturing a piezoelectric oscillator described above, preferably, in the providing process of the piezoelectric vibrators, the piezoelectric vibrators provided on the common semiconductor substrate are connected to each other by a common wiring layer provided on the common semiconductor substrate, and a part of the common wiring layer is led out as electrodes. In the performing process of the electrical inspection, the electrical inspection is performed separately or simultaneously for the piezoelectric vibrators by using the common wiring layer.

In the invention, the piezoelectric vibrators are connected (in parallel) to each other due to the wiring layer formed on the common semiconductor substrate. By causing each of the piezoelectric vibrators (and corresponding electrical circuits) to be grounded or supplying a inspection signal to each of the piezoelectric vibrators (and corresponding electrical circuits) using the wiring layer, it is possible to perform the electrical inspection of each of the piezoelectric vibrators (and corresponding electrical circuits) mounted on the common semiconductor substrate. At this time, the electrical inspection may be performed separately for each of the plurality of piezoelectric vibrators (and corresponding electrical circuits). Alternatively, the electrical inspection may be performed at the same time for each of the plurality of piezoelectric vibrators (and corresponding electrical circuits). Accordingly, it is possible to efficiently perform the electrical inspection of the piezoelectric oscillator at each stage. This makes it possible to manufacture the piezoelectric oscillator at a lower cost than before.

Further, in the method of manufacturing a piezoelectric oscillator described above, preferably, the common wiring layer has a multi-layered wiring structure. An external connection terminal of each of the piezoelectric vibrators is connected to a part of wiring of an uppermost layer of the common wiring layer.

Since the multi-layered wiring structure is adopted, the degree of freedom of pattern or size of an uppermost wiring layer in the multi-layered wiring structure is improved. Accordingly, the degree of freedom of mounting of the piezoelectric vibrators and the degree of freedom of arrangement of the external electrodes are also improved. This makes it possible to manufacture the piezoelectric oscillators more efficiently.

Furthermore, in the method of manufacturing a piezoelectric oscillator described above, preferably, the method further includes a process of forming a resin layer so as to cover the piezoelectric vibrators and the external electrodes between the forming process of the external electrodes and the performing process of the electrical inspection.

In the invention, after a process of forming the external electrodes, the resin layer is formed to fix the piezoelectric vibrators and the external electrodes to each other. Then, a process of performing the electrical inspection of each piezoelectric vibrator (and a corresponding electrical circuit) is performed. The resin layer can be easily formed by resin potting or the like. There occurs no particular problem in forming the resin layer. As a result, it is possible to efficiently manufacture highly reliable piezoelectric oscillators.

Preferably, the providing process of the piezoelectric vibrators includes: forming the piezoelectric vibrators in a state that the piezoelectric vibrators are arranged on the same base; and positioning the base with respect to the semiconductor substrate and fixing the piezoelectric vibrators and the semiconductor substrate to each other.

Preferably, the forming process of the resin layer includes a process of filing a gap between the external electrode and the semiconductor substrate with an epoxy resin so as to cover the piezoelectric vibrators and a part of the external electrodes.

In the invention, a chip-size mounting structure is adopted as a mounting structure of piezoelectric oscillators. As a result, each piezoelectric oscillator can be made small, thin, and low price.

That is, in the piezoelectric oscillator of the invention, it is not necessary to accommodate a semiconductor chip in a recessed part of a ceramic substrate, unlike the related art. Accordingly, since it is not necessary to consider a positioning margin or the like, the planar size of a piezoelectric oscillator is basically determined by a semiconductor chip size. In addition, the piezoelectric oscillator can be made sufficiently thin because the ceramic substrate is not provided, and it is possible to manufacture the piezoelectric oscillator at a low cost because the expensive ceramic substrate is not needed.

In the invention, in the case of a semiconductor chip size of 2.0 mm×1.6 mm, for example, it is possible to realize a piezoelectric oscillator having a size of 2.0 mm×1.6 mm.

Further, since a multi-layered wiring structure is adopted,.degree of freedom of pattern or size of an uppermost wiring layer in the multi-layered wiring structure is improved. Accordingly, degree of freedom of mounting of piezoelectric vibrators and degree of freedom of arrangement of external electrodes are also improved. This contributes to making the piezoelectric oscillator much smaller and thinner.

Furthermore, since a resin layer is formed, protection of piezoelectric vibrators is enhanced. In addition, since piezoelectric vibrators and external electrodes are fixed due to resin, the mechanical strength is increased. Accordingly, it becomes possible to realize a highly reliable piezoelectric oscillator.

Furthermore, in the invention, the electrical inspection of each piezoelectric vibrator is completed under a state in which the plurality of piezoelectric vibrators is mounted on a common semiconductor substrate. Accordingly, it is sufficient to perform a simple inspection for piezoelectric oscillators separated by dicing, or it may be possible to omit the inspection. As a result, it is possible to reduce the time consumption for the electrical inspection.

In the invention, it is possible to efficiently manufacture a piezoelectric oscillator that has a new structure in which a ceramic substrate is not used and that is thin, small, and low price. As a result, it is possible to produce piezoelectric oscillators in large quantities.

In addition, since the degree of freedom of mounting of the piezoelectric vibrators and the degree of freedom of arrangement of the external electrodes are improved due to adoption of the multi-layered wiring structure, it is possible to manufacture the piezoelectric oscillator more efficiently.

Moreover, since an electrical inspection process is performed after forming the resin layer, highly reliable piezoelectric oscillators can be efficiently manufactured. The resin layer can be easily formed by resin potting or the like. There occurs no particular problem in forming the resin layer.

### BRIEF DESCRIPTION OF THE DRAWINGS

The above objects and advantages of the present invention will become more apparent by describing in detail preferred exemplary embodiments thereof with reference to the accompanying drawings, wherein:

FIGS. 1A to 1C are views illustrating an example (example in which a chip-size mounting structure is applied) of a piezoelectric oscillator according to an embodiment of the invention, FIG. 1A is a cross-sectional view of the piezoelectric oscillator, FIG. 1B is a side view of the piezoelectric oscillator, and FIG. 1C is a top view of the piezoelectric oscillator;

FIG. 2 is a cross-sectional view illustrating an example (example in which a resin layer is formed) of a piezoelectric oscillator according to another embodiment of the invention;

FIG. 3 is a cross-sectional view illustrating an example (example in which a wiring layer on a semiconductor chip has a multi-layered structure) of a piezoelectric oscillator according to still another embodiment of the invention;

FIG. 4 is a cross-sectional view illustrating an example (example in which a wiring layer on a semiconductor chip has a multi-layered structure and a resin layer is formed) of a piezoelectric oscillator according to still another embodiment of the invention;

FIGS. 5A to 5D are cross-sectional views illustrating a device in each process in order to explain an example of a method of manufacturing a piezoelectric oscillator of the invention;

FIGS. 6A to 6E are cross-sectional views illustrating a device in each process in order to explain another example of a method of manufacturing a piezoelectric oscillator of the invention

FIGS. 7A to 7H are cross-sectional views illustrating a device in each process in order to explain another example of a method of manufacturing a piezoelectric oscillator of the invention;

FIGS. 8A to 8I are cross-sectional views illustrating a device in each process in order to explain another example of a method of manufacturing a piezoelectric oscillator of the invention;

FIGS. 9A to 9H are cross-sectional views illustrating a device in each process in order to explain another example of a method of manufacturing a piezoelectric oscillator of the invention; and

FIG. 10 is a cross-sectional view illustrating an example of the configuration of a piezoelectric oscillator in the related art.

### DETAILED DESCRIPTION OF THE PREFERRED EMBODIMENTS

Hereinafter, embodiments of the invention will be described with reference to the accompanying drawings.

### First Embodiment

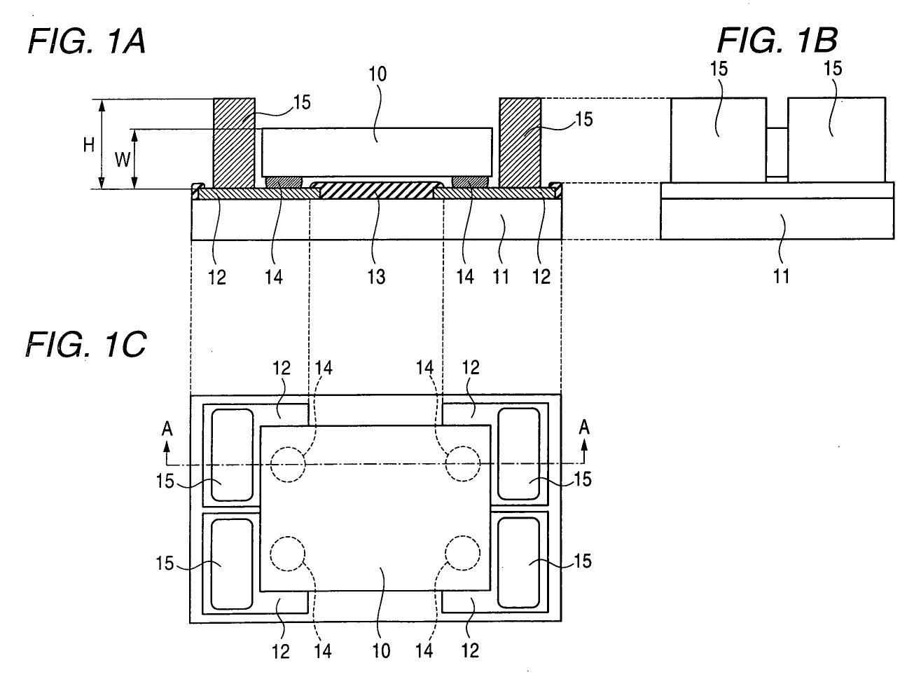

FIGS. 1A to 1C are views illustrating an example (example in which a chip-size mounting structure is applied) of a piezoelectric oscillator according to an embodiment of the invention. FIG. 1A is a cross-sectional view of the piezoelectric oscillator, FIG. 1B is a side view of the piezoelectric oscillator, and FIG. 1C is a top view of the piezoelectric oscillator.

In FIG. 1, reference numeral 10 denotes a piezoelectric vibrator, reference numeral 11 denotes a semiconductor chip, reference numeral 12 denotes a wiring layer formed on the semiconductor chip, reference numeral 13 denotes a protective layer for the semiconductor chip 11, reference numeral 14 denotes a bump electrode (hereinafter, may simply referred to as an ‘electrode’), and reference numeral 15 denotes an electrode post (external electrode).

A plurality of the electrode posts 15 are provided on the wiring layer 12 so as to be correspond to the bump electrodes 14 respectively. The electrode posts 15 are substantially shaped in a square pillar (rectangular solid). The height H of the electrode post 15 is greater than the thickness W (including the thickness of the bump electrode 14) of the piezoelectric vibrator 10. Accordingly, surface mounting becomes possible by connecting a set substrate (not shown) onto an upper surface (top surface) of the electrode post 15. The electrode post 15 may be formed by repetitively coating solder using a screen printing method, for example.

Here, the electrode post 15 is provided in this embodiment, however, a wire may be provided as a substitute for the electrode post 15.

The piezoelectric vibrator 10 is electrically connected to the semiconductor chip 11 and the wiring layer 12 through the bump electrode 14 and electrically connected to the set substrate or the like through the electrode post 15. In order to electrically connect the electrode post 15 and the set substrate with each other, a conductive adhesive may be used, or a solder bump or the like may be additionally formed on a surface of the electrode post 15 connected to the set substrate.

As shown in FIG. 1A, the wiring layers 12 are formed on the main face of the semiconductor chip 13. However, the wiring layers 12 may be provided in the semiconductor chip 13 as a part of the semiconductor chip 13.

The piezoelectric oscillator shown in FIG. 1 has a structure in which only the piezoelectric vibrator 10 and the semiconductor chip 11 are stacked to overlap in the vertical direction, without using a ceramic substrate. Accordingly, since it is not necessary to consider the dimensional allowance for inner walls of the ceramic substrate or semiconductor chip mounting unlike the related art, the size of a semiconductor chip can become that of the piezoelectric oscillator.

Thus, it is possible to make the piezoelectric oscillator in a size significantly reduced as compared with the structure in the related art.

In addition, since the structure in which only the piezoelectric vibrator 10 and the semiconductor chip 11 are stacked to overlap in the vertical direction is adopted, each piezoelectric oscillator can be made thin.

Moreover, since the expensive ceramic substrate is not used, it is possible to provide piezoelectric oscillators at a low price.

### Second Embodiment

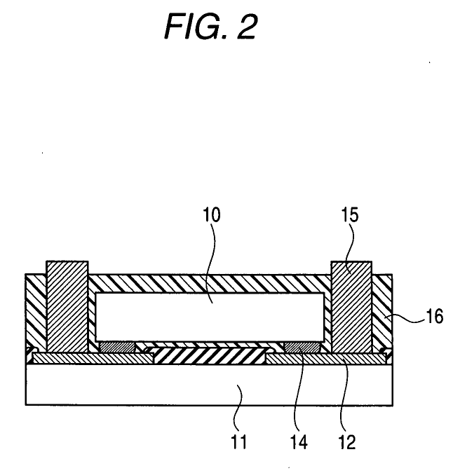

FIG. 2 is a cross-sectional view illustrating an example (example in which a resin layer is formed) of a piezoelectric oscillator according to another embodiment of the invention. The same elements as in FIG. 1 are denoted by the same reference numerals, and a detailed description thereof will be omitted.

In the configuration shown in FIG. 2, reference numeral 16 denotes a resin layer that covers the piezoelectric vibrator 10 (and most of the side part of the electrode post 15) and is formed of an epoxy resin or the like. In the manufacturing process of the piezoelectric oscillator, the epoxy resin is filled with the piezoelectric oscillator in a state that the piezoelectric vibrators and electrode posts are mounted on the semiconductor substrate.

Preferably, the resin layer is constituted by a resin material wherein the degree of viscosity is from 4 Pa·s to 15 Pa·s, and a normal hardening condition is 70° C.×50 min or 80° C.×20 min.

Since the piezoelectric oscillator having the configuration shown in FIG. 2 is provided with the resin layer 16, the mechanical strength of the piezoelectric oscillator is improved and the semiconductor chip is protected more safely. Therefore, it is possible to improve the reliability of the piezoelectric oscillator in addition to being made small (scale down), thin, and low price in the same manner as in the piezoelectric oscillator shown in FIG. 1.

That is, since the piezoelectric vibrator 10 is covered by the resin layer 16, the piezoelectric vibrator 10 is protected more safely. Accordingly, the reliability of a dust-proof or moisture-resistant surface is improved. In addition, since the semiconductor chip 11 and the electrode post 15 are fixed due to the resin layer 16, the mechanical strength of the piezoelectric oscillator is improved. As a result, it is possible to improve quality and reliability of the piezoelectric oscillator. The resin layer covering the piezoelectric vibrator and the electrode post is formed of the epoxy resin having high flowability and low viscosity. Since the epoxy resin fills a gap among the piezoelectric vibrator 10, the bump electrode 14, the electrode post 15 and the semiconductor chip 14, a fixing strength of the element with respect to the semiconductor chip 11 is enhanced.

### Third Embodiment

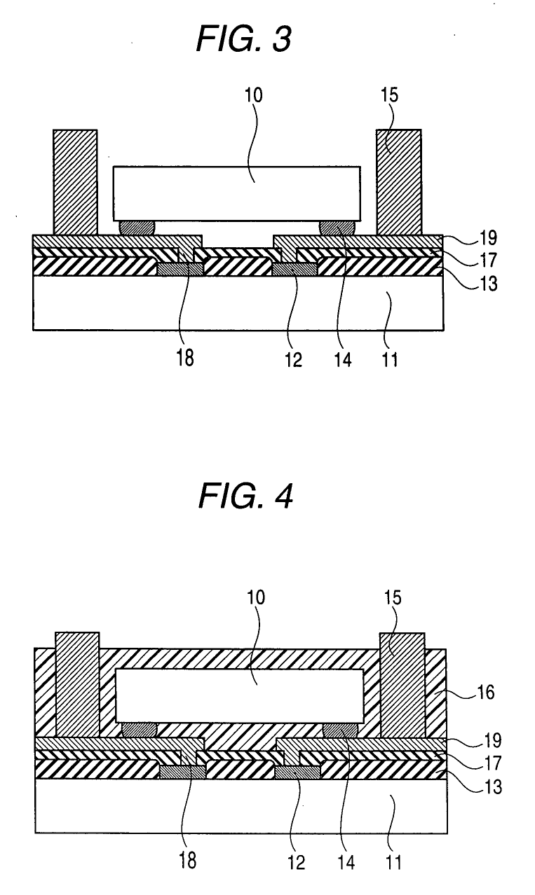

FIG. 3 is a cross-sectional view illustrating an example (example in which a wiring layer on a semiconductor chip has a multi-layered structure) of a piezoelectric oscillator according to still another embodiment of the invention. In FIG. 3, the same elements as in the previous drawings are denoted by the same reference numerals, and a detailed description thereof will be omitted.

In FIG. 3, reference numeral 17 denotes an interlayer insulating layer, reference numeral 18 denotes a through hole formed on the interlayer insulating layer 18, and reference numeral 19 denotes a wiring layer (second wiring layer) formed on the interlayer insulating layer 17.

The interlayer insulating layer 17 is formed on a semiconductor chip for which a normal preprocess is completed, and then the through hole 18 is formed for electrical connection with the semiconductor chip 11.

After forming the through hole 18, the wiring layer 19 is formed to be electrically connected to the semiconductor chip 11. Then, the electrode 14 of the piezoelectric vibrator 10 is connected to the wiring layer 19. As a result, the piezoelectric vibrator 10 is electrically connected to an electric circuit within the semiconductor chip 11. Then, the electrode post 15 is connected to the wiring layer 19, thereby forming a piezoelectric oscillator that has a chip size and is thin and low price.

Further, since the piezoelectric oscillator shown in FIG. 3 has a multi-layered conductive wiring structure on the semiconductor chip 11, the uppermost wiring layer 19 can be freely patterned. Accordingly, degree of freedom of arrangement of the electrode posts 15 and position of the first wiring layer 12 formed on the semiconductor chip 11 is increased. This contributes to making the piezoelectric oscillator much thinner and smaller.

Furthermore, even though an example in which the wiring layer has a two-layered wiring structure is shown in FIG. 3, the invention is not limited thereto. For example, a multi-layered wiring structure including three or more layers may be adopted in the present embodiment. In addition, in order to improve the reliability, a protective layer (passivation layer) may be additionally formed on the uppermost wiring layer 19.

### Fourth Embodiment

FIG. 4 is a cross-sectional view illustrating an example (example in which a wiring layer on a semiconductor chip has a multi-layered structure and a resin layer is formed) of a piezoelectric oscillator according to still another embodiment of the invention. In FIG. 4, the same elements as in the previous drawings are denoted by the same reference numerals, and a detailed description thereof will be omitted.

In the piezoelectric oscillator shown in FIG. 4, the semiconductor chip 11 and the electrode post 15 are fixed due to the resin layer 16. Accordingly, it is possible to improve the reliability and quality of the piezoelectric oscillator in addition to obtaining the same effects as the piezoelectric oscillator shown in FIG. 3.

### Fifth Embodiment

In the present embodiment (and embodiments subsequent to the present embodiment), a manufacturing method of allowing the piezoelectric oscillator of the invention to be effectively produced in large quantities will be described.

This method is characterized in that a piezoelectric vibrator is mounted at wafer level and sealed with a resin layer and then the wafer is divided into separate semiconductor chips.

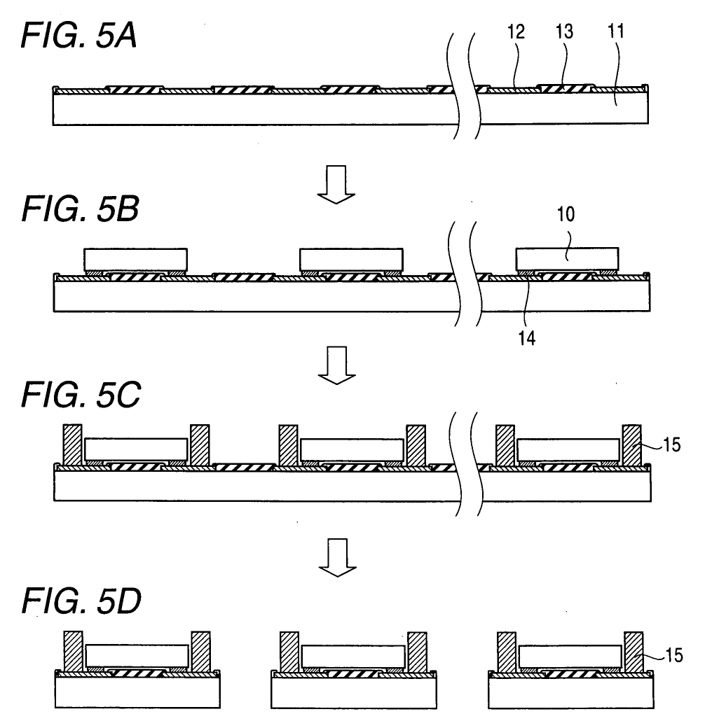

FIGS. 5A to 5D are cross-sectional views illustrating a device in each process in order to explain an example of a method of manufacturing a piezoelectric oscillator of the invention. In FIGS. 5A to 5D, the same elements as in the previous drawings are denoted by the same reference numerals.

(Processes Shown in FIGS. 5A and 5B)

FIG. 5A illustrates a semiconductor substrate (including a semiconductor wafer (semiconductor chip 11), the wiring layer 12, and the protective layer 13 and serving as a common base for collectively manufacturing a plurality of piezoelectric oscillators) for which preprocess is completed. As shown in FIG. 5B, the piezoelectric vibrators 10 are mounted on the semiconductor substrate (11, 12, and 13). That is, the piezoelectric vibrators 10 are fixed such that the bump electrodes (electrodes) 14 of the piezoelectric vibrators 10 are connected to the wiring layer 12.

Here, the piezoelectric vibrators may be fixed on the semiconductor substrate by attaching the piezoelectric vibrators 10 on a wafer-sized base and then positioning the piezoelectric vibrators 10 at the same time before dicing.

(Process Shown in FIG. 5C)

In a process shown in FIG. 5C, the electrode posts 15 are formed as external electrodes on the wiring layer 12. Then, in this process, an electrical inspection is performed separately or simultaneously for the piezoelectric oscillators. The electrode posts 15 are formed using a screen printing method or the like, but may be formed before mounting the piezoelectric vibrator. In this case, the electrode posts 15 may be formed using a plating method or the like. Alternatively, the electrode posts 15 may be formed as follows. That is, a metal plate adhered on a wafer-sized film substrate is processed in a photolithographic method and etching method so as to form the electrode posts 15, the formed electrode posts 15 are positioned on the semiconductor substrate (wafer) and the electrode posts 15 are fixed using solder or the like, and then the film substrate is detached and removed.

That is, by electrically connecting a plurality of piezoelectric oscillators with each other through a wiring layer and causing a part of the wiring layer to be led out as electrodes on the semiconductor substrate, an electrical inspection of the piezoelectric oscillators can be performed before dicing the semiconductor substrate. In this case, it becomes possible to simplify or omit the electrical inspection after cutting into the piezoelectric oscillators. Thus, it is possible to reduce time consumption for the electrical inspection.

In addition, in the case when dicing of the semiconductor substrate is not performed yet, it may be possible to perform the electrical inspection for the plurality of piezoelectric oscillators at the same time. Thus, it is possible to greatly reduce the time consumption for the electrical inspection.

(Process Shown in FIG. 5D)

In a process shown in FIG. 5D, separate piezoelectric oscillators are obtained by dicing the semiconductor substrate. Thus, it is possible to efficiently and inexpensively manufacture the piezoelectric oscillators that are small, thin, and low price.

### Sixth Embodiment

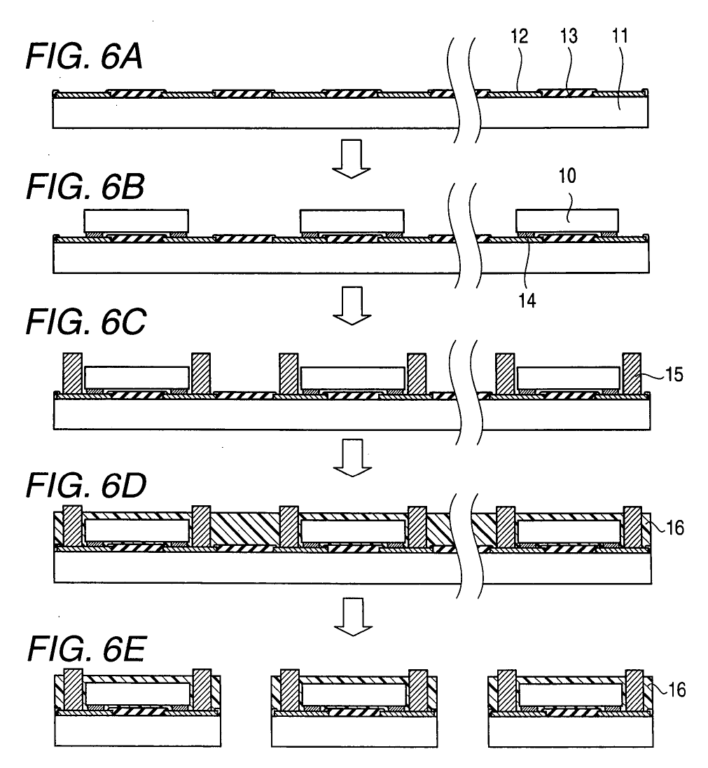

FIGS. 6A to 6E are cross-sectional views illustrating a device in each process in order to explain another example of a method of manufacturing a piezoelectric oscillator of the invention. In FIGS. 6A to 6D, the same elements as in the previous drawings are denoted by the same reference numerals.

FIGS. 6A to 6C are processes corresponding to FIGS. 5A to 5C. Subsequently, in a process shown in FIG. 6D, the resin layer 16 is formed and the piezoelectric vibrators 10 and the electrode posts 15 are fixed by the resin layer 16. Thus, by performing dicing after improving the mechanical strength and protective performance by fixing the piezoelectric vibrators 10 and the electrode posts 15 using the resin layer 16, it becomes possible to provide a very reliable piezoelectric oscillator.

Even in this case, it is possible to improve the reliability by enhancing protection of the piezoelectric vibrator 10 and also to improve the quality and reliability due to improvement of the mechanical strength. In addition, in this process, an electrical inspection is performed separately or simultaneously for the piezoelectric oscillators.

Here, by electrically connecting a plurality of piezoelectric oscillators with each other through a wiring layer and causing a part of the wiring layer to be led out as electrodes on the semiconductor substrate, an electrical inspection of the piezoelectric oscillators can be performed before dicing the semiconductor substrate. In this case, it becomes possible to simplify or omit the electrical inspection after cutting into the piezoelectric oscillators. Thus, it is possible to reduce time consumption for the electrical inspection.

In addition, in the case when dicing of the semiconductor substrate is not performed yet, it may be possible to perform the electrical inspection for the plurality of piezoelectric oscillators at the same time. Thus, it is possible to greatly reduce the time consumption for the electrical inspection.

Then, in a process shown in FIG. 6E, separate piezoelectric oscillators are obtained by dicing the semiconductor substrate. Thus, it is possible to efficiently and inexpensively manufacture the piezoelectric oscillators that are small, thin, and low price.

### Seventh Embodiment

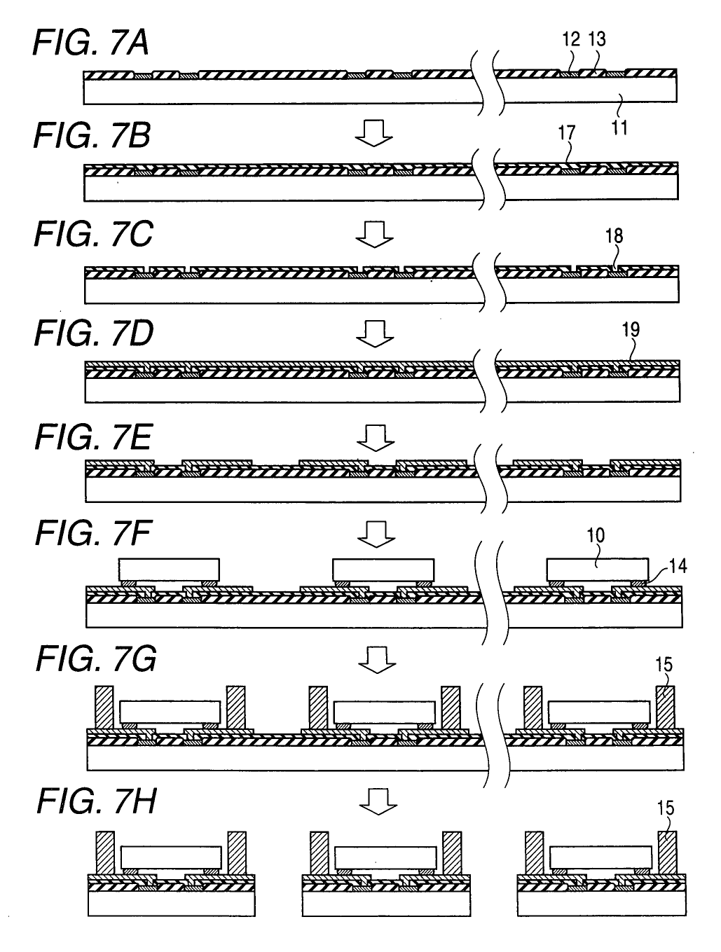

FIGS. 7A to 7H are cross-sectional views illustrating a device in each process in order to explain another example of a method of manufacturing a piezoelectric oscillator of the invention. In FIGS. 7A to 7H, the same elements as in the previous drawings are denoted by the same reference numerals.

In a process shown in FIG. 7A, a semiconductor substrate (semiconductor chip 11, first wiring layer 12, and protective layer 13) for which preprocess is completed is prepared.

In a process shown in FIG. 7B, the interlayer insulating layer 17 is formed on the semiconductor substrate. Then, In a process shown in FIG. 7C, the through holes 18 are formed in the interlayer insulating layer 17.

In a process shown in FIG. 7D, the wiring layer 19 is formed. In a process shown in FIG. 7E, an unnecessary part of the wiring layer 19 is removed.

In a process shown in FIG. 7F, the electrodes 14 of the piezoelectric vibrators 10 are connected to the wiring layer 19 so as to fix the piezoelectric vibrators 10.

Subsequently, in a process shown in FIG. 7G, the electrode posts 15 are formed as external electrodes. Then, in this process, an electrical inspection is performed separately or simultaneously for the piezoelectric oscillators.

Then, in a process shown in FIG. 7H, separate piezoelectric oscillators are obtained by dicing the semiconductor substrate. Thus, it is possible to efficiently and inexpensively manufacture the piezoelectric oscillators that are small, thin, and low price.

### Eighth Embodiment

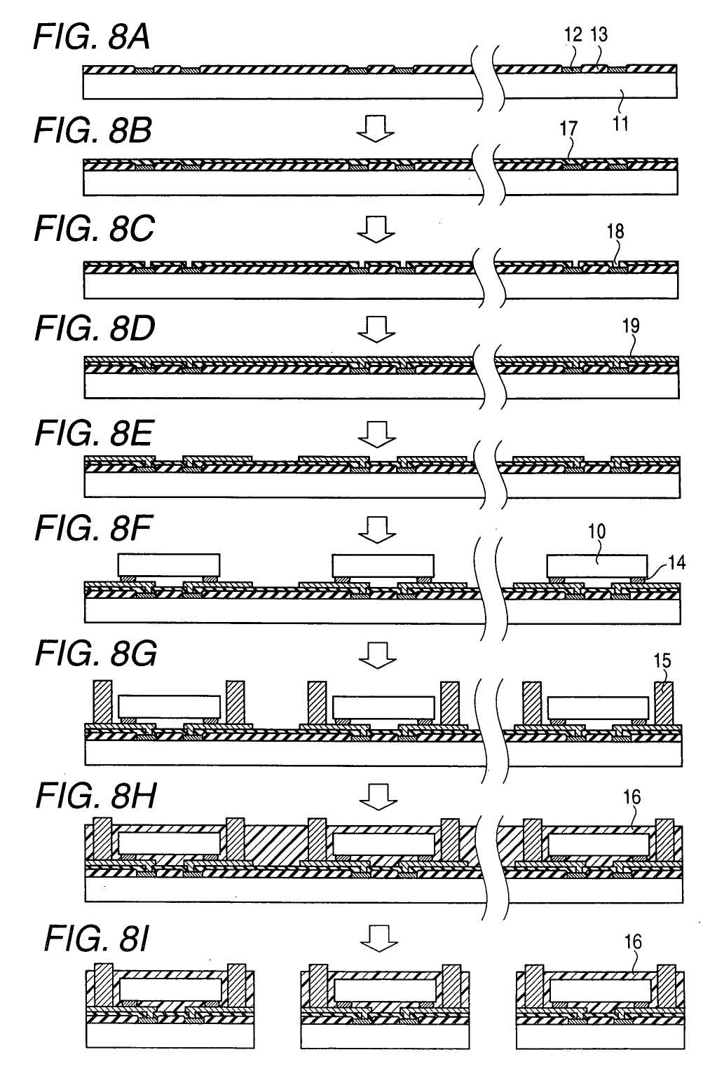

FIGS. 8A to 8I are cross-sectional views illustrating a device in each 20 process in order to explain another example of a method of manufacturing a piezoelectric oscillator of the invention. In FIGS. 8A to 8I, the same elements as in the previous drawings are denoted by the same reference numerals.

FIGS. 8A to 8G are processes corresponding to FIGS. 7A to 7G. Subsequently, in a process shown in FIG. 8H, the resin layer 16 is formed. Due to the formed resin layer 16, the piezoelectric vibrators 10 and the electrode posts 15 are fixed. Accordingly, it is possible to improve the reliability by enhancing protection of the piezoelectric vibrator 10 and also to improve the quality and reliability due to improvement of the mechanical strength. In addition, in this process, an electrical inspection is performed separately or simultaneously for the piezoelectric oscillators.

By electrically connecting a plurality of piezoelectric oscillators with each other through a wiring layer and causing a part of the wiring layer to be led out as electrodes on the semiconductor substrate, an electrical inspection of the piezoelectric oscillators can be performed before dicing the semiconductor substrate. In this case, it becomes possible to simplify or omit the electrical inspection after cutting into the piezoelectric oscillators. Thus, it is possible to reduce time consumption for the electrical inspection. In addition, in the case when dicing of the semiconductor substrate is not performed yet, it may be possible to perform the electrical inspection for the plurality of piezoelectric oscillators at the same time. Thus, it is possible to greatly reduce the time consumption for the electrical inspection.

Then, in a process shown in FIG. 8I, separate piezoelectric oscillators are obtained by dicing the semiconductor substrate. Thus, it is possible to efficiently and inexpensively manufacture the piezoelectric oscillators that are small, thin, and low price.

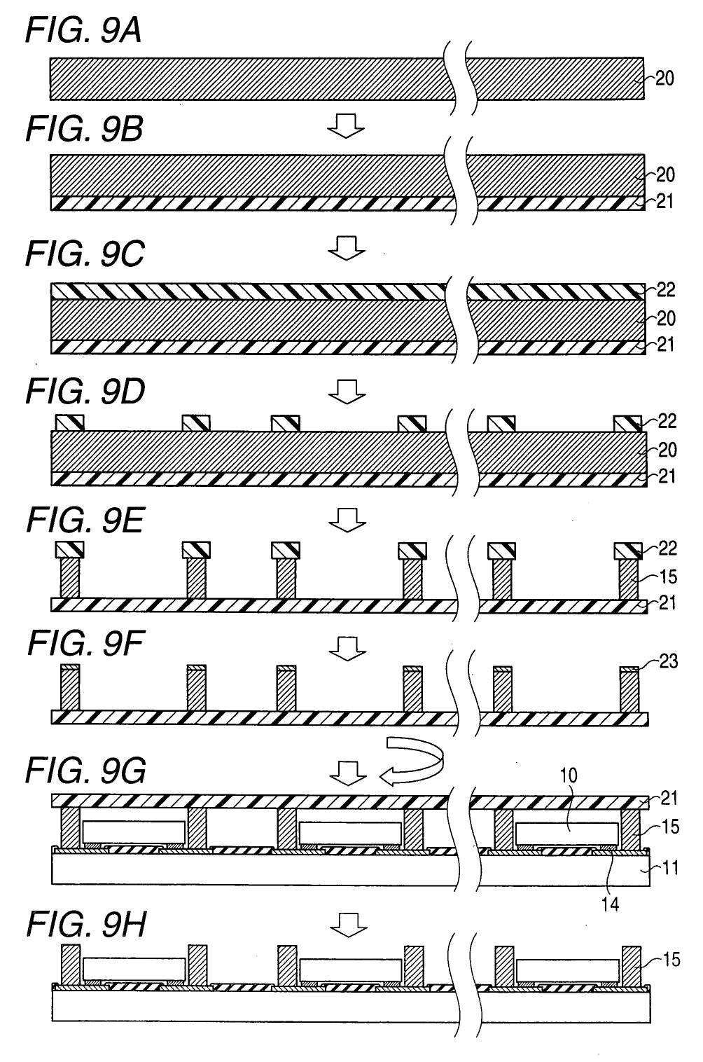

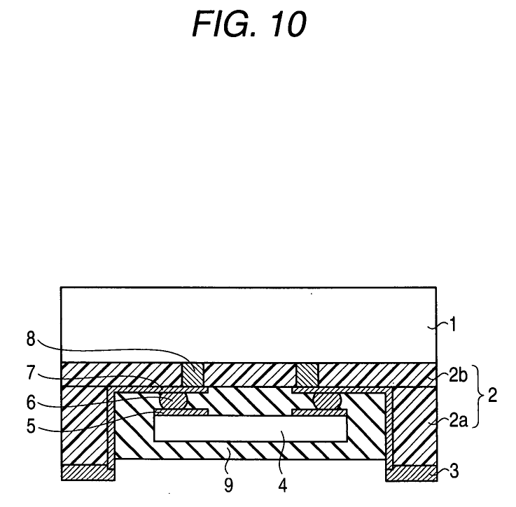

FIGS. 9A to 9H are cross-sectional views illustrating a device in each process in order to explain another example of a method of manufacturing a piezoelectric oscillator of the invention. In FIGS. 9A to 9H, the same elements as in the previous drawings are denoted by the same reference numerals. In this embodiment, a method of efficiently manufacturing electrode posts in mass production will be explained.

A metal plate 20 is prepared in FIG. 9A. A film substrate 21 is adhered to the metal plate 20 in FIG. 9B. A resist 22 is applied to the metal plate 20 in FIG. 9C.

Next, in FIG. 9D, the resist 22 is patterned by the photolithography method, and a pattern in which the resists 22 on the metal plate 20 are remained is formed. In FIG. 9E, the metal plate 20 is etched by using the resists 22 on the metal plate 20 as the mask to form a plurality of the electrode posts 15. In FIG. 9F, the resists 22 are eliminated from the respective electrode posts 15 by ashing method, and then, conductive adhesive materials are coated ends of the respective electrode posts 15.

Next, in FIG. 9G, a set of the electrode posts 15 is adhesive to a plurality modules having the piezoelectric vibrators respectively and so on are provided on a semiconductor substrate (silicon wafer) in a state that the film substrate provided with the electrode posts 15 is arranged in an upside down condition. In FIG. 9H, the film substrate 21 is removed from the electrode posts 15.

The succeeding process after the above processes are performed are same as the processes after the process shown in FIG. 8H of the eight embodiment is performed. Therefore, detailed explanation is omitted. However, as shown in FIG. 9H, the resin layer 16 is formed in a state that the semiconductor substrate 11 provided with the electrode posts 15 is in wafer level condition (FIG. 8H). The piezoelectric vibrators 10 and the electrode posts 15 are fixed by the resin layer 16. Therefore, the protection of the piezoelectric vibrators 10 is enhanced and the reliability of the piezoelectric oscillator can be increased. Further, the quality and reliability is increased due to improvement of the mechanical strength. In addition, in this process, an electrical inspection is performed separately or simultaneously for the piezoelectric oscillators.

By using the above manufacturing processes, the providing of the piezoelectric vibrators and the forming of the electrode posts are achieved in wafer level. Therefore, the piezoelectric oscillator provided with the electrode posts can be efficiently manufactured in mass production.

As described above, according to the embodiments of the invention, a chip-size mounting structure is adopted as a mounting structure of piezoelectric oscillators. As a result, each piezoelectric oscillator can be made small, thin, and low price.

That is, according to the embodiments of the invention, it is not necessary to accommodate a semiconductor chip in a recessed part of a ceramic substrate, unlike the related art. Accordingly, since it is not necessary to consider a positioning margin or the like, the planar size of a piezoelectric oscillator is basically determined by a semiconductor chip size. In addition, the piezoelectric oscillator can be made sufficiently thin because the ceramic substrate is not provided, and it is possible to manufacture the piezoelectric oscillator at a low cost because the expensive ceramic substrate is not needed.

According to the embodiments of the invention, in the case of a semiconductor chip size of 2.0 mm×1.6 mm, for example, it is possible to realize a piezoelectric oscillator having a size of 2.0 mm×1.6 mm.

Further, since a multi-layered wiring structure is adopted, degree of freedom of pattern or size of an uppermost wiring layer is improved. Accordingly, degree of freedom of mounting of piezoelectric vibrators and degree of freedom of arrangement of electrode posts are also improved. This also contributes to making the piezoelectric oscillator much smaller and thinner.

Furthermore, since a resin layer is formed, protection of piezoelectric vibrators is enhanced. In addition, since piezoelectric vibrators and electrode posts are fixed due to resin, the mechanical strength is increased. Accordingly, it becomes possible to realize a highly reliable piezoelectric oscillator.

According to the embodiments of the invention, since dicing is performed after mounting piezoelectric vibrators on a semiconductor substrate at wafer level, the piezoelectric vibrators can be positioned at the same time. As a result, it is possible to simplify a manufacturing process.

In addition, according to the embodiments of the invention, the electrical inspection of each piezoelectric vibrator is completed under a state in which the plurality of piezoelectric vibrators is mounted on a common semiconductor substrate. Accordingly, it is sufficient to perform a simple inspection for piezoelectric oscillators separated by dicing, or it may be possible to omit the inspection. As a result, it is possible to reduce the time consumption for the electrical inspection.

Thus, it is possible to efficiently manufacture a piezoelectric oscillator that has a new structure in which a ceramic substrate is not used and that is thin, small, and low price. As a result, it is possible to produce piezoelectric oscillators in large quantities.

In addition, since the degree of freedom of mounting of the piezoelectric vibrators and the degree of freedom of arrangement of the electrode posts are improved due to adoption of the multi-layered wiring structure, it is possible to manufacture the piezoelectric oscillator more efficiently.

Moreover, since an electrical inspection process is performed after forming the resin layer, highly reliable piezoelectric oscillators can be efficiently manufactured. The resin layer can be easily formed by resin potting or the like. In particular, there occurs no problem in forming the resin layer.

### INDUSTRIAL APPLICABILITY

The invention is advantageous in that a piezoelectric oscillator, which has a new structure in which a ceramic substrate is not used and which is thin, small, and low price, is realized and the efficient structure of the piezoelectric oscillator is realized. Thus, the invention is useful for a piezoelectric oscillator and a method of manufacturing the same.

What is claimed is:

1. A piezoelectric oscillator, comprising:
a semiconductor chip which includes an electrical circuit;
a piezoelectric vibrator which is provided on a main surface of the semiconductor chip; and
an external electrode which is provided on the main surface of the semiconductor chip.

2. The piezoelectric oscillator according to claim 1, wherein a height of the external electrode is greater than a thickness of the piezoelectric vibrator.

3. The piezoelectric oscillator according to claim 1, wherein the piezoelectric vibrator is electrically connected to the electrical circuit through a wiring layer provided on the semiconductor chip; and
wherein the external electrode is electrically connected to the electrical circuit through the wiring layer.

4. The piezoelectric oscillator according to claim 3, wherein the wiring layer is configured by a multi-layered wiring structure; and
wherein the wiring layer includes:
a first wiring layer;
an interlayer insulating layer which covers the first wiring layer; and
a second wiring layer which is connected to the first wiring layer through a contact hole provided in the interlayer insulating layer.

5. The piezoelectric oscillator according to claim 3, wherein a resin layer is formed on the main surface of the semiconductor chip so as to cover the piezoelectric vibrator and a part of the external electrode.

6. The piezoelectric oscillator according to claim 3, wherein the external electrode is substantially shaped in a square pillar.

7. The piezoelectric oscillator according to claim 5, wherein the resin layer is comprised of an epoxy resin.

8. A method of manufacturing a piezoelectric oscillator, comprising:
providing a plurality of piezoelectric vibrators on a common semiconductor substrate;
forming a plurality of external electrodes so as to be correspond to the piezoelectric vibrators;
performing an electrical inspection of each of the piezoelectric vibrators in a state that the piezoelectric vibrators are provided on the common semiconductor substrate; and
dicing the common semiconductor substrate so that a plurality of piezoelectric oscillators are individually cut out, each of the piezoelectric oscillators having a configuration in which each of the piezoelectric vibrators is provided on a semiconductor chip.

9. The method of manufacturing the piezoelectric oscillator according to claim 8, wherein a height of each of the external electrodes is greater than a thickness of each of the piezoelectric vibrators.

10. The method of manufacturing the piezoelectric oscillator according to claim 8, wherein, in the providing process of the piezoelectric vibrators, the piezoelectric vibrators provided on the common semiconductor substrate are connected to each other by a common wiring layer provided on the common semiconductor substrate, and a part of the common wiring layer is led out as electrodes; and
wherein, in the performing process of the electrical inspection, the electrical inspection is performed separately or simultaneously for the piezoelectric vibrators by using the common wiring layer.

11. The method of manufacturing the piezoelectric oscillator according to claim 10, wherein the common wiring layer has a multi-layered wiring structure; and
wherein an external connection terminal of each of the piezoelectric vibrators is connected to a part of wiring of an uppermost layer of the common wiring layer.

12. The method of manufacturing the piezoelectric oscillator according to claim 8, further comprising:
forming a resin layer so as to cover the piezoelectric vibrators and the external electrodes between the forming process of the external electrodes and the performing process of the electrical inspection.

13. The method of manufacturing the piezoelectric oscillator according to claim 8, wherein the providing process of the piezoelectric vibrators includes:
forming the piezoelectric vibrators in a state that the piezoelectric vibrators are arranged on the same base; and
positioning the base with respect to the semiconductor substrate and fixing the piezoelectric vibrators and the semiconductor substrate to each other.

14. The method of manufacturing the piezoelectric oscillator according to claim 8, wherein the external electrode is substantially shaped in a square pillar.

15. The method of manufacturing the piezoelectric oscillator according to claim 12, the forming process of the resin layer includes:
filing a gap between the external electrode and the semiconductor substrate with an epoxy resin so as to cover the piezoelectric vibrators and a part of the external electrodes.
